(19) United States
(12) Patent Application Publication
(10) Pub. No.: US 2024/0376590 A1
(43) Pub. Date: Nov. 14, 2024

(54) METHOD FOR DEPOSITING CARBON ON A SUBSTRATE

(71) Applicant: HYDROMECANIQUE ET FROTTEMENT, Andrezieux-Boutheon (FR)

(72) Inventors: Marie-Alix LEROY, Saint-Etienne (FR); Michaël OUGIER, Saint Chamond (FR)

(73) Assignee: HYDROMECANIQUE ET FROTTEMENT, Andrezieux-Boutheon (FR)

(21) Appl. No.: 18/686,184

(22) PCT Filed: Aug. 30, 2022
(86) PCT No.: PCT/FR2022/051631

§ 371 Date: Feb. 23, 2024

(30) Foreign Application Priority Data
Aug. 31, 2021 (FR) 2109116

(51) Int. Cl. C23C 14/35; C23C 14/06; H01M 4/86; H01M 4/88; H01M 8/0206; H01M 8/0213; H01M 8/0228; H01M 8/10

(52) U.S. Cl. CPC C23C 14/35; C23C 14/0605; H01M 4/8631; H01M 4/8657; H01M 4/8663; H01M 4/8871; H01M 8/0206; H01M 8/0213; H01M 8/0228; H01M 2004/8694; H01M 2008/1095; H01M 2250/20

(57) ABSTRACT

The invention relates to a method for depositing a carbon-based material from a target onto a metal substrate, by ion-assisted cathode sputtering.

According to the invention, the ratio between the flow of ions that is directed toward the substrate and the flow of neutral carbon atoms that is directed toward the substrate is adjusted to between 1.7 and 3.5; and a bias voltage of between −35 V and −100 V is applied to the substrate.

### TECHNICAL FIELD

The invention relates to the technical field of vacuum surface treatment, and in particular of physically depositing carbon in the vapour phase on a substrate.

### PRIOR ART

The invention relates to electrochemical systems, such as fuel cells and batteries, and in particular, proton exchange membrane fuel cells (PEMFC).

The operation of these electrochemical systems involves an acid or basic environment, oxidising to the cathode, a temperature being able to be from 60 to 160° C., and the optional presence of halides. This environment favours the corrosion of the elements of said system, such as interconnecting plates, also called electrodes, interconnectors or bipolar or monopolar plates.

In particular, bipolar plates are critical components for the durability of these systems: they are constituted of metal sheets, the thickness of which is around 100 μm. They must be protected by a coating, in order to preserve a good electrical conduction on the surface, and in order to avoid the corrosion of metal sheets in the aggressive medium of the cell.

The surface conduction of a bipolar plate made of metal material, including in a corrosive medium, is generally obtained by depositing a carbon- or gold-based functional layer on the extreme surface of a substrate. The prior deposition of a sublayer on the substrate can improve the adherence of the functional layer and ensure a good mechanical resistance of the stack.

Generally, the adherence between the layer and the substrate, as well as the mechanical strength of the functional layer, which is conveyed by an absence of damage by cracking or by delamination, are important parameters.

Particularly, the barrier function of this layer must not be degraded, and the functional layer must remain hermetic to the reactive species present in the medium (for example, O₂, H⁺, halides) over the operating duration of the electrochemical system, to protect the metal substrate from oxidation, in order to prevent the emission in the medium of the cell of metal cations coming from the substrate, even in low quantity.

In the case of use of the power supply of an electric vehicle, the cell must have a significant service life, of around 10000 hours, while preserving acceptable performance. During such a long duration of use, accidental phenomena can occur, such as a depletion of reagent, or also a local drying or flooding of the cell. These accidental phenomena can lead to local and transitional increases of temperature, of potential, or of current density. In addition, independently of the accidental phenomena, the conditions of switching on and of stopping the electrochemical system, mainly of transitional system, can lead to overpotential at the electrodes.

These local and generally temporary variations of the conditions of the electromechanical system increasingly urge the functional layer, within which defects such as lacks, cracks, holes, intercolumn spaces, can cause a rapid degradation of the substrate, in particular by galvanic coupling with the functional layer.

Furthermore, when the membrane of the cell is made of fluoropolymer, it can release F⁻ ions which together promote corrosion by pitting of the stainless steel substrates. This can then lead to a rapid and catastrophic failure of the entire cell.

In order to protect a cell from such failures, by meeting the mechanical strength and electrical conduction objectives described above, it is known from the prior art to deposit a functional layer, in particular carbon-based, by proceeding with an input of additional energy during the deposition.

Document WO2020019693A1 describes the deposition of a carbon-based functional layer, during which the substrate is heated to a high temperature, i.e. between 40° and 500° C., in order, in particular, to densify the deposited layer. These high temperatures are able to cause significant residual stresses in the stack after treatment. This can be damaging for the adherence of the coating, and in particular its deformation resistance, if the forming of the plate is done after the deposition.

There are other deposition methods, but have the following disadvantages:
Arc evaporation deposition technologies cause growth defects in the layer in the form of droplets, which are damaging for the resistance of the deposition over significant operating durations, and this, all the more than the layer is thick, i.e. around 100 nm or more.
Filtered arc deposition or high-power impulse magnetron sputtering (HIPIMS) technologies involve low deposition speeds.
Unbalanced configuration magnetron sputtering deposition technologies, optionally closed-field, can be difficult to be used for an efficient production on an industrial scale of a large number of parts.
Ion beam bombardment-enhanced deposition does not make it possible to effectively bombard large part surfaces, as the ion beam must scan the entire surface area of the part. The flow density is therefore insufficient and incompatible with significant deposition speeds necessary for industrial operation productivity.

The methods described in the prior art do not make it possible to obtain an electrochemical system, the performance associated with the yield of which remains sufficiently high over a long service life of such a system, and quite specifically, for electric vehicles.

An aim of the invention is therefore to overcome the disadvantages of the prior art described above.

The invention aims, in particular, to provide a method for depositing a material comprising carbon on a substrate, making it possible to form a carbon material layer ensuring a good coverage of the substrate, having few defects and therefore few mechanical weaknesses, while having a good electrical conduction.

The invention also aims to provide such a method, which is efficient and inexpensive to implement, given the improved properties of the deposited layer described, that the method aims to obtain.

### SUMMARY OF THE INVENTION

To this end, a deposition method has been developed with ion assistance of a carbon-based material from a target onto a metal substrate, by cathode sputtering.

According to the invention, the ratio between the flow of ions directed toward the substrate and the flow of neutral carbon atoms directed towards the substrate is adjusted between 1.7 and 3.5, and a bias voltage of between −35V and −100V is applied to the substrate.

The adjustment, on the one hand, of the ratio between the flow of ions and the flow of neutral carbon atoms between 1.7 and 3.5, and on the other hand, of the bias voltage of the substrate between −35 Volts and −100 Volts, which returns to adjusting the energy of the ions of ion assistance between 35 eV and 100 eV (electronvolts), makes it possible to obtain a carbon-based layer having a good adherence, which ensures a good coverage of the substrate, while having few defects regarding the deposited layers according to known methods. This reduction of defects within the layer, in particular of cracks or delaminated regions, is conveyed by obtaining a dense layer, which optimally protects the underlying substrate, thus avoiding the risks of contamination of the electrochemical medium and improving the service life of the electrochemical system.

This combination of specific values of the ratio between the flow of ions and the flow of neutral carbon atoms, and the bias voltage of the substrate, leads to a carbon-based layer which further has a good electrical conduction, as well as an intrinsic corrosion resistance.

These optimised properties are essential, quite specifically in the scope of manufacturing a monopolar or bipolar plate comprising a metal substrate, in particular within a cell, which is also an aim of the present invention.

Further to the properties described above, and consequently to the latter, the part obtained by the method of the invention, which has an external surface comprising the metal substrate coated with a layer of the carbon-based material, is mainly characterised in that the carbon-based material layer comprises less than 1% at of oxygen. This oxygen rate is a ratio of the number of oxygen atoms with respect to the number of carbon atoms within the layer of the carbon-based material. Such a part, which can be obtained by the method of the invention such as described above, constitutes another aim of the invention.

This oxygen ratio less than 1% at of oxygen conveys a low contamination of the carbon-based layer by the oxygen. This ratio is characteristic of the invention. Indeed, the correct implementation of the invention makes it possible to obtain this ratio and through that, to avoid the recurrent difficulty until now of disposing of oxygen in carbon-based depositions, as oxygen can come from the residual vacuum, or from the carbon target which is always porous (the porosity can reach 10% of the volume of the target).

It is specified that the carbon-based material layer is preferably deposited by continuous magnetron sputtering, opposed to pulsed.

It is reminded that an ion assistance is characterised by the quantity of ions directed toward the growth material layer, as well as by the energy of these ions. The flow of ions is directed toward the substrate and the bias of the latter accelerates the flow of ions. These interactions between the ions and the substrate occur in the proximity of the substrate.

The ions which bombard the growth layer come from the magnetron cathode (for example, in the case of an unbalanced magnetron cathode sputtering), and when a complementary plasma source is present, from the magnetron cathode and said complementary plasma source.

The flow of ions therefore comprises the ions from the gaseous mixture, wherein the plasma is generated, such as argon ions for example, and optionally ions coming from the target. Whatever the nature of the ions, they bombard the growth layer which makes it possible to densify it.

The ion assistance is not necessarily simultaneous to the cathode sputtering.

They can operate alternately, such that:
the substrate receives a first quantity of carbon-based material by sputtering,
then the ion assistance is implemented to densify the deposited material.

The substrate thus passes in front of the carbon source then in front of the ion source, repeatedly.

The alternances are chosen according to the cathode sputtering method and according to the design of the installation implementing the deposition method. In practice, the sputtering and ion assistance systems can operate continuously, while the part to be coated scrolls successively in front of said systems. Clearly, it is considered that when the ion assistance is implemented, the associated flow of ions is always greater than zero, i.e. that the flow of ions is non-zero, otherwise the ion assistance could not fulfil its role.

The flow of neutral carbon atoms is oriented from the target to the substrate. It mainly comprises carbon atoms, constituting the material layer to be deposited, coming from the target.

The flow of ions and flow of neutral carbon atoms values are time and space averages, calculated from measurements. Indeed, it is understood that in practice, the substrates to be covered are movable in the installation, while the magnetron cathode and the plasma source are fixed. The substrates do not receive the same quantities of ions and carbon atoms according to their positioning at a given instant.

The bias voltage of the substrate, or more simply, the bias of the substrate, is defined as being the potential difference applied between the substrates and the ground of the device implementing the method. This bias can be continuous or pulsed. In the latter case, the bias voltage is the average value of the voltage applied to the substrates. The bias current is the (average) intensity measured on the biased substrate.

The (kinetic) energy of the ions is given to them by the acceleration in the electrical field which is around the substrates. It is linked to the bias voltage and is calculated by multiplying the absolute value of the potential difference between the substrate and the plasma by the electrical charge of the particle or of the species considered. Generally, it is considered that the potential of the plasma with respect to the ground is insignificant before the potential difference between the ground and the parts. This returns to considering that the energy of the monocharged ions in eV corresponds to the voltage delivered by the bias generator in volts.

In order to simplify the implementation of the method and, in particular, taking measurements or evaluating magnitudes, the following features can be taken individually or according to their technically possible combinations:
the flow of ions is determined from the bias current of the substrate, and the flow of neutral carbon atoms is determined from the deposition speed of the material on the metal substrate;
the flow of (monocharged) ions can be determined by dividing the bias current by the surface of the substrates exposed to the plasma, in order to obtain an average bias current density, then by dividing said bias current density by the elementary charge.
the flow of neutral carbon atoms is determined by multiplying the deposition speed of the material on the metal substrate by the density of the material, and by then dividing by the molar mass of the material, then by multiplying the result obtained by the Avogadro constant.

In order to further improve the properties of the deposited carbon-based layer, in particular concerning the mechanical strength, the electrical conduction, and the resistance to corrosion, the ratio between the flow of gaseous ions and the flow of neutral carbon atoms is preferably between 2 and 3.1.

In these cases, preferably, and with an aim of optimising the method, a bias voltage is chosen of between −50V and −75V.

Still in this case, also preferably, for reasons of optimising the method, the deposition in a chamber under controlled atmosphere can also be performed, and the working pressure of which is between 1×10⁻⁶ bar and 4×10⁻⁶ bar, preferably between 2.0×10⁻⁶ bar and 2.6×10⁻⁶ bar.

For the protection of the substrate to be sufficient in case of operating incidents or local variations of operating parameters, in particular in case of overpotentials linked to transitional or accidental systems for operating the electrochemical system, the material deposited on the substrate forms a layer called thin layer, having a thickness greater than or equal to 20 nm, preferably of between 20 nm and 500 nm, more preferably between 50 nm and 250 nm, even more preferably between 80 nm and 150 nm, and more preferably between 80 nm and 120 nm.

In a particular embodiment adapted to the field of fuel cells, the substrate comprises a stainless steel, titanium, a titanium alloy, or a nickel-, chromium- and iron-based alloy, which is preferably an Inconel®.

Preferably, the substrate is a plate of thickness of between 10 μm and 1000 μm.

In a first embodiment, the flow of ions (of ion assistance) is generated by a magnetron cathode, for example when the method consists of an unbalanced magnetron cathode sputtering.

In a second embodiment, the flow of ions is generated by a system complementary to the magnetron cathode, preferably by microwave plasma.

With an aim of equipment productivity and rationalisation, and optionally, the substrate scrolls within an installation in front of a magnetron cathode sputtering station, then in front of a plasma generation station, preferably cyclically.

In order to improve the adherence of the carbon-based material deposited on the substrate, and to protect the substrate from a possible oxidation, the method can comprise a prior step of depositing a metal sublayer on the substrate, intended to be located between the substrate and the carbon-based material, in contact with said substrate, the material of the metal sublayer being chosen from among one or more of the following materials: chromium, titanium, zirconium, tantalum, or their alloys, as well as their nitrides and carbides, and preferably titanium or tantalum, or their alloys (alloys comprising titanium and/or tantalum), as well as their nitrides and carbides.

In order to have a favourable compromise between the duration of depositing the metal sublayer and the improvement of the adherence that it gives, its thickness is between 5 nm and 100 nm, preferably between 20 nm and 40 nm.

In order to improve the adherence of the carbon-based material deposited on the substrate, and to improve the resistance to corrosion, the method can comprise a prior step of depositing a carbon-based sublayer on the substrate, intended to be located between the substrate and the carbon-based material described above, said sublayer being in contact with said carbon-based material.

The carbon-based sublayer is preferably constituted of the same material as the overlying layer of carbon-based material. The choice of carbon as the material of the sublayer makes it possible to only use one single sputtering target within the magnetron, which therefore makes it possible to simplify the implementation of the method.

To perform the deposition of the carbon-based sublayer, the ratio between the flow of ions directed toward the substrate and the flow of neutral carbon atoms directed toward the substrate is adjusted to a value less than 1, and preferably less than 0.5, the flow of ions being non-zero. The bias voltage applied to the substrate is between −35V and −100V, preferably −50V and −75V.

In order to have a favourable compromise between the duration of depositing the carbon-based sublayer and the improvement of the adherence that it gives, its thickness is between 2 nm and 40 nm, preferably between 10 nm and 30 nm.

The implementation of the method according to the abovementioned features and comprising a step of a carbon-based material from a target onto a metal substrate by magnetron cathode sputtering, therefore enables the functionalisation of a monopolar or bipolar plate comprising said metal substrate covered by a layer comprising said carbon-based material, for example by ensuring a durable protection against the corrosion of a bipolar plate, while maintaining, over time, a high surface electrical conduction level.

The invention therefore also relates to a method for manufacturing a monopolar or bipolar plate comprising a metal substrate covered by a layer comprising a carbon-based material. This method comprises a step of depositing said carbon-based material from a target onto said metal substrate, by magnetron cathode sputtering, according to the deposition method described above.

The invention further relates to a part which can be obtained by a method for depositing a carbon-based material from a target onto a metal substrate, by ion-assisted cathode sputtering, such as described above. Said part has an external surface comprising said metal substrate coated with a layer of the carbon-based material. The carbon-based material layer comprises less than 1% at of oxygen, calculated as the number of oxygen atoms with respect to the number of carbon atoms within the carbon-based material layer.

### BRIEF DESCRIPTION OF THE DRAWINGS

FIG. 1 is a schematic representation, as a top view, of an installation for the implementation of the method according to the invention.

FIG. 2 is a schematic representation, as a top view, of another installation for the implementation of the method according to the invention.

FIG. 3 is a graph illustrating the corrosion current density of carbon-based material layers deposited on substrates obtained during several series of tests, according to the ratio between the flow of ions and the flow of neutral carbon atoms during their deposition.

FIG. 4 is a micrograph illustrating the stripping after corrosion test of a substrate coated with a deposition not according to the invention.

FIG. 5 is a cyclic voltammetry graph in a chlorinated environment led over carbon-based material layers deposited on stainless steel substrates according to the ratio between the flow of ions and the flow of neutral carbon atoms, obtained during several series of tests.

FIG. 6 is a detailed view of the graph of FIG. 5.

FIG. 7 is a graph illustrating the interfacial contact resistance of 100 nm carbon-based material layers deposited on substrates according to the ratio between the flow of ions and the flow of neutral carbon atoms, as well as the current density of corrosion, obtained during several series of tests.

FIG. 8 is an observation of a cut made in electron microscopy by electron scanning of a substrate treated according to the method of the invention.

FIG. 9 is a graph illustrating the evolution of the corrosion current density of carbon-based material layers deposited on substrates over time, obtained during several series of tests.

FIG. 10 is a graph illustrating the oxygen content (measured by nuclear reaction analysis “NRA”) of carbon-based material layers obtained during several tests, deposited on substrates according to the ratio between the flow of ions and the flow of neutral carbon atoms.

FIG. 11 is a photograph of a monopolar plate.

FIG. 12 is a partial representation of a cut of such a plate.

### DETAILED DESCRIPTION OF THE INVENTION

In the field of surface treatment, there are several types of technologies, and each has its advantages and its disadvantages. In the scope of treating parts, and in particular, monopolar or bipolar plates for the fuel cells, the Applicant has sought to optimise known deposition methods.

Based on the known and industrialisable technology of ion-assisted magnetron cathode sputtering deposition, the Applicant has performed different series of tests and interpretations aiming to obtain a deposition of a carbon-based material (M), forming a layer on a substrate (S), and having good properties, in particular, of mechanical strength, resistance to corrosion, adherence, and electrical conduction.

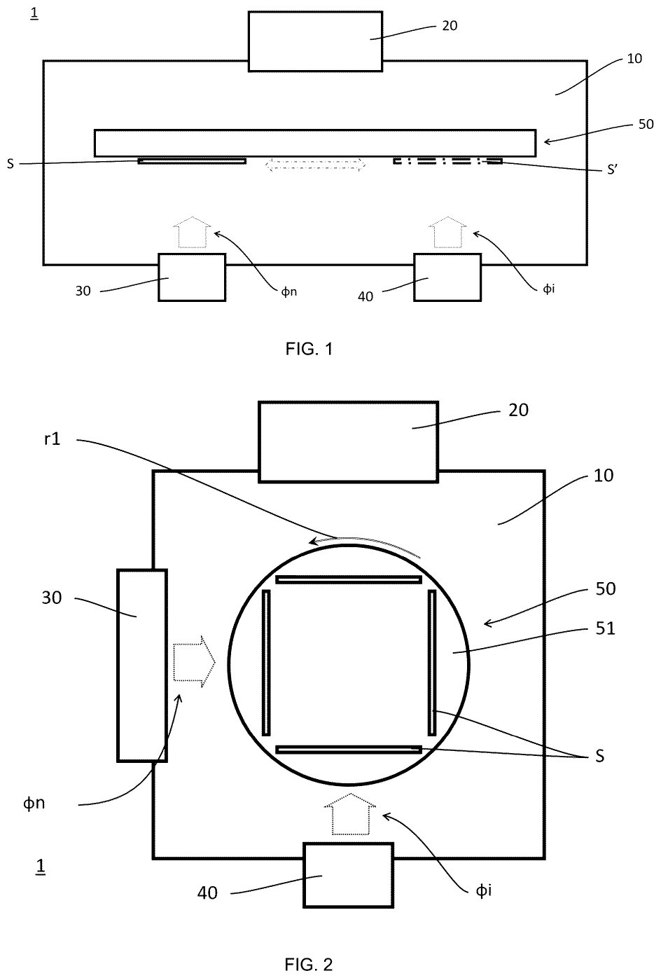

In reference to FIGS. 1 and 2, the installation (1) used to implement a preferred embodiment of the method comprises a secondary vacuum chamber (10), provided with a pumping system (20), a conventional (balanced or unbalanced) magnetron sputtering source (30), a complementary plasma source (40) generating a gaseous ion plasma (P), and a substrate carrier (50) on which the substrates (S) to be treated are mounted.

The pumping system (20) makes it possible to obtain a secondary vacuum in the chamber (10), i.e. a pressure of an order of magnitude of between 10⁻⁸ mbar and 10⁻³ mbar. The pumping system (20), or another independent system, is capable of introducing a gas (rare gas) in the vacuum chamber (10). The gas is intended to be ionised, this is preferably argon.

The magnetron sputtering source (30), is a conventional magnetron (30), supplied continuously. In this embodiment, the ions of the flow (φi) are generated by a plasma source (40) complementary to the magnetron cathode (30). The plasma source (40) is of any suitable type, but the plasma (P) is preferably generated by microwaves.

In other embodiments, the ions of the flow (φi) are generated by the magnetron cathode (30), in particular in the case where the magnetron is unbalanced. An unbalanced magnetron has an unbalanced magnetic structure, which makes it possible to send some of the ions generated by the plasma of the cathode to the parts.

The plasma source (40) is therefore optional and its presence depends on the type of magnetron sputtering implemented and on the quantity of ions available to generate a sufficient flow of ions (φi).

In any case, it is possible to add several magnetron cathodes (30) to deposit the material (M) quicker on the substrate (S), in which case, each cathode is supplied by its own generator.

The substrate carrier (50) is biased, i.e. that a negative voltage or potential difference is applied at its terminals, in order to accelerate the gaseous ions of the plasma and thus create a flow of ions (φi) in the direction of the substrate carrier (50). This acceleration of the gaseous ions occurs in the vicinity of the substrates (S), since the electrical field which results from the biasing of the parts extends over a short distance, of around 1 mm to 3 mm.

Whatever the sputtering mode considered, ions are attracted onto the material (M) target of the magnetron, in order to sputter it and emit the atoms which form the deposition on the substrate (S). It is not these ions which the Applicant is interested in, in the present invention. Indeed, these are the ions attracted onto the substrate (S), where the material (M) deposition grows which define the ion assistance, and which are important for the quality of the deposited layer. In the scope of the application, the ions are constituted of gaseous species, preferably like argon.

The role of these ions is to bombard the material (M) deposition by growth on the substrate to compact it and remove the species not forming sufficiently stable bonds with the atoms of the material. This makes it possible to increase the density of the growth material (M) layer, and to remove the oxygen in said growth material (M) layer. Care must however be taken, to not eject the material (M) already placed on the substrate (S), in order to not slow down the deposition or degrade the quality of the current deposition.

Generally, the ions of the plasmas coming from the magnetron cathodes or auxiliary plasma sources of the microwave plasma type are “slow”. They therefore have no power to compact a growth material (M) layer or remove oxygen from this layer. Thus, and as indicated above, a negative voltage is applied to the substrate (S) to be coated, which attracts and accelerates the positive ions to said substrates (S). The bias voltage is between −35V and −100V, and preferably between −50V and −75V.

In the case of biasing a substrate (S) in a plasma (P), the bias voltage is applied between the substrates (S) and the ground of the installation (1). A potential difference is established between the substrates (S) and the plasma (P). It is in this potential drop zone, over around 1 to 3 mm of the surface of the substrates (S), that the ions are accelerated.

The kinetic energy of the ions is similar to the potential difference between the plasma (P) and the substrates (S). In most plasmas, the potential of the plasma is known, but it is generally a few Volts, for example, +5V to +10V. In practice, the potential of the plasma (P) is similar to 0V when the voltage applied to the substrates (S) reaches a few tens of volts as an absolute value.

This approximation is valid at low pressure, as the ions are not slowed down by collisions in the acceleration phase in the proximity of the substrates (S).

The acceleration of these ions being proportional to their charge and to the potential difference, the bias voltage is assimilated to the energy given to the ions during the deposition, by multiplying this bias voltage by the charge of an electron. Indeed, in the technical field considered, the ions are generally monocharged.

In the installation (1) illustrated in FIG. 1, the substrate carrier (50) is of the carriage type, i.e. that it comprises a linear actuator to drive a substrate (S) in translation and alternatively in front of the magnetron (30) in order to receive the material (M), then in a position (S′) in front of the plasma source (40) such that the impacts of gaseous ions compact the deposited material (M) layer. In this case, the installation is disposed by length.

In the installation (1) illustrated in FIG. 2, the substrate carrier (50) is of the revolving type, i.e. that it comprises a plate (51) on which one or more substrates (S) are disposed, and this plate (51) is driven in a rotation (r1). In this way, each substrate (S) scrolls alternatively in front of a magnetron cathode sputtering station, then in front of a plasma generation station (P).

According to the exact implementation and the size of the substrates, additional rotations can, naturally, be superposed to the rotation (r1) of the plate.

In each of these embodiments, it is advantageous to dispose several magnetron cathodes (30) alternately with several plasma sources (40). In this way, the movement of the substrate (S) is continuous, and this scrolls alternatively in front of a magnetron cathode sputtering station, then in front of a plasma generation station (P). Adding magnetron cathodes (30) alternately with plasma sources (40) makes it possible to increase the productivity of the installation (1).

In any case, the substrate carrier (50) can be of any suitable type according to the substrates (S) to be treated or to the construction of the installation (1), this also being able to be disposed vertically or horizontally or adapted by shape and by dimensions.

In order to be able to evaluate the performance of the material (M) layer deposited on the substrate (S), the following measurements are taken.

The service life of the deposited material layer is evaluated by making it undergo a corrosion test.

The electrochemical tests are performed in an acid solution of pH equal to 3 (H₂SO₄), at 80° C. and with 0.1 ppm of fluoride ion. These parameters are defined by the DOE (Department Of Energy) in the United States of America to simulate the operating medium of a PEMFC. The potential is set to +0.8V on the working electrode on which the material to be tested is mounted, with respect to the reference electrode Ag/AgCl. The addition of an air bubble makes it possible to simulate the cathode behaviour of a fuel cell.

The corrosion current is an image of the degradation speed of a part comprising a substrate (S) having received a material (M) layer. Indeed, the greater the corrosion current is, the more the part is in the process of being oxidised, i.e. that the material (M) layer poorly fulfils its protective role. In practice, a corrosion current density less than 300 nA/cm² after 24 hours under a potential of 0.8V is considered acceptable.

The surface conductivity of the coating is evaluated by the measurement of its interfacial contact resistance, or “ICR”. A coating having a good surface conductivity has a low ICR, for example less than 10 mΩ·cm².

The ICR measurement is taken on a stack composed of a Copper—Carbon Sheet block (GDL—Gas Diffusion Layer)—Deposition on substrate—Nickel paint (rear face of the substrate)—Copper block, on which a current of 100 mA is applied for a surface area of 1 cm², then the resistance of the assembly is calculated from the voltage measured.

This stack is representative of the coated bipolar plate/GDL contact. A pressure of 138N/cm² is applied on this by a lever arm system with weights, this pressure being representative of that applied on an electrochemical cell during its assembly.

The resistance Rₜₒₜₐₗ obtained is the sum of (equation 1):
Of the resistance of the Cu—Cu system (R_{offset})
Once the Copper Carbon R_{Cu/C} interfacial contact resistance
Once the resistance of the Carbon RC felt (zero)
Of the resistance of the 316L R316L steel platelet (zero)
Of the linear resistance of the deposition R_{deposition}
Of the interfacial contact resistance between the deposition and the Carbon R_{C/deposition}.
Once the Nickel Copper R_{Ni/Cu} interfacial contact resistance

$$\begin{matrix}[ Math . 1 ] & \\ {R}_{total} = {R}_{offset} + {R}_{Cu / C} + {R}_{C / deposition} + {R}_{deposition} + {R}_{Ni / Cu} & ( 1 )\end{matrix}$$

The ICR is determined using the equation (2).

$$\begin{matrix}[ Math . 2 ] & \\ {R}_{C / deposition} + {R}_{deposition} = RCI = {R}_{total} - {R}_{offset} - {R}_{Cu / C} - {R}_{Ni / Cu} & ( 2 )\end{matrix}$$

The ICR can be measured before or after a corrosion test, in which case the latter simulates an accelerated ageing of the treated parts.

As needed, it is possible to make cuts of the samples, for example, by ion beam (focused ion beam—FIB) in order to observe the morphology of the deposited layer. It is also possible to perform other chemical characterisation tests of the deposited layer, for example by NRA

The principle of the NRA method is based on the nuclear reaction study between the kernels of a flow of high energy incident ions and the atoms of the target at rest. The sample is placed in the analysis chamber under a vacuum of 2E-6 torrs, that is 3×10⁻⁹ bar, the zone to be studied facing the incident particle beam. The latter is constituted by a flow of ions 2H⁺ of energy equal to 930 keV, and forms, on the target, an incident current of 250 nA for an analysis surface area of a few mm². The backscattered particles coming from the nuclear reaction of the 16O(d,p)17O type are detected at 150° from the initial direction and after treatment by the acquisition chain will form spectra. The detector is screened by a 10 μm thick mylar sheet. The comparison with a reference standard of alumina (O: 720E15 at/cm²) makes it possible to determine for a given integrated total charge, the quantity of oxygen present in each sample. Knowing, according to the density of the material, the quantity of carbon present in the volume of analysed material, the ratio between the atomic quantity of oxygen and of carbon can then be obtained.

Within the installation (1), several series of tests have been performed. The substrates (S) used are stainless steel test pieces 316L intended to be coated on their two faces, in order to simulate the coating of bipolar plates.

The substrate (S) is positioned on a mounting, it is cleaned and blasted to remove the contaminants and dust possibly present on its surface. It is then introduced into a vacuum deposition installation (1).

The pumping system (20) is activated, such that the pressure in the chamber (10) is less than 5×10⁻⁹ bar, and the chamber (10) is heated to remove the water adsorbed on its walls.

The surfaces of the substrate (S) to be coated are heated and bombarded to remove the water adsorbed on the surfaces and strip the chromium oxide layer present on the surface.

The pumping system (20) then introduces argon into the chamber (10), such that there is an argon pressure of 2.5×10⁻⁶ bar.

The magnetron cathode (30) is powered with a power of 3.2 kW in order to sputter a graphite carbon target, and a potential of −55V with respect to the ground of the installation (1) is applied in pulsed mode to the substrate (S). The substrate (S) is thus coated for 5 minutes.

Then an auxiliary plasma source (40) is illuminated in order to generate a sufficient flow of ions (φi). The plasma source (40) is maintained at a power of 500 W (flow ratio of 2.7), such that the current density on the substrate carrier (50) reaches 2.5 A/m². The rest of the deposition is performed with an alternating sputtering of the target on the magnetron cathode (30) and of ion bombardment by the plasma source (40), over a total duration of 25 minutes.

With this first example, a 100 nm carbon layer is thus obtained on the two faces of the substrate (S). The chamber (10) is then vented and the substrate (S) is recovered.

A first series of preliminary tests is performed by modifying:
the deposition durations which provides a more or less thick deposited layer;
the power of the ion assistance; and
the presence or not of a sublayer (SC) making it possible to improve the resistance of the material (M) layer on the substrate (S).

The power applied to the magnetron cathode (30), therefore the deposition speed, remains constant. The compliance of the tests is evaluated by measuring the ICR and by the resistance to the corrosion of the deposited layers.

In order to use quantitative measurements and that the scaling of the method is possible, the cathode power magnitudes of the magnetron (30) and of the ion assistance are conveyed:
by flow (φn) of neutral carbon atoms for the cathode power of the magnetron (30); and
by flow (φi) of ions for the ion assistance.

In this case, the flow (φn) of neutral carbon atoms received by the substrate is determined from the deposition speed of the layer considered expressed in cm/s, multiplied by the density of the carbon layer (2.1 g·cm⁻³), divided by the molar mass of the carbon (12 g/mol) and then multiplied by Avogadro's constant, which gives a number of carbon atoms per cm² and per s.

The density of the deposited carbon has been verified by electron energy loss spectroscopy, in order to validate that the carbon density data available in literature would correspond well to the deposited carbon.

The calculation of the flow (φn) of neutral carbon atoms is an average: by dividing the thickness of the deposition by the deposition duration, an average deposition speed is determined, despite the fact that the deposition is only formed during the passage of the substrates (S) in front of the magnetron cathode (30). However, there is actually the entire surface of the substrate (S) which is coated for the total duration of the deposition, and it is therefore as if the entire surface permanently received the flow of neutral carbon atoms (φn) thus calculated.

For calculating the flow of ions (φi), it is proceeded with similarly: the total bias current in A is divided by the biased total surface area in cm², which gives an average current density on the substrates (S) in A/cm². By dividing it by the elementary charge, a flow of ions per cm² and per s is obtained.

Although the plasma (P) is located at the plasma source (40) and that the bombardment of substrates (S) occurs in the proximity of it, the total current collected by the substrates (S) is the same as in the case where all of the surface constantly receives an average ion bombardment, therefore an average current density.

The ratio between the flow of ions (φi) and the flow (φn) of neutral carbon atoms directed toward the substrate (S) therefore has no unit.

The results obtained are indicated in the table below.

TABLE 1

| | | Thickness | | Power on | | | |
|---|---|---|---|---|---|---|---|
| | Metal | of the layer | | the auxiliary | | Flow ration φi/φn | |
| Tests | sublayer | of C | | plasma source | | during deposition | Performance |
| Example 1 | No | 100 | nm | 500 | W | 2.7 | Excellent |
| Example 2 | Ti, 30 nm | 100 | nm | 500 | W | 2.7 | Excellent |
| Example 3 | No | 100 | nm | 0 | W | 0.3 | Insufficient |
| Example 4 | No | 100 | nm | 1200 | W | 4.1 | Insufficient |
| Example 5 | No | 20 | nm | 500 | W | 2.7 | Correct |
| Example 6 | Ti, 30 nm | 20 | nm | 500 | W | 2.7 | Correct |
| Example 7 | Ti/TiC | 20 | nm | 500 | W | 2.7 | Correct |
| | gradient, 30 nm | | | | | | |
| Example 8 | No | 100 | nm | O W then 500 W | | 0.3 | Insufficient |
| | | | | after deposition | | | |
| Example 9 | Ti, 30 nm | 100 | nm | 1200 | W | 4.1 | Insufficient |

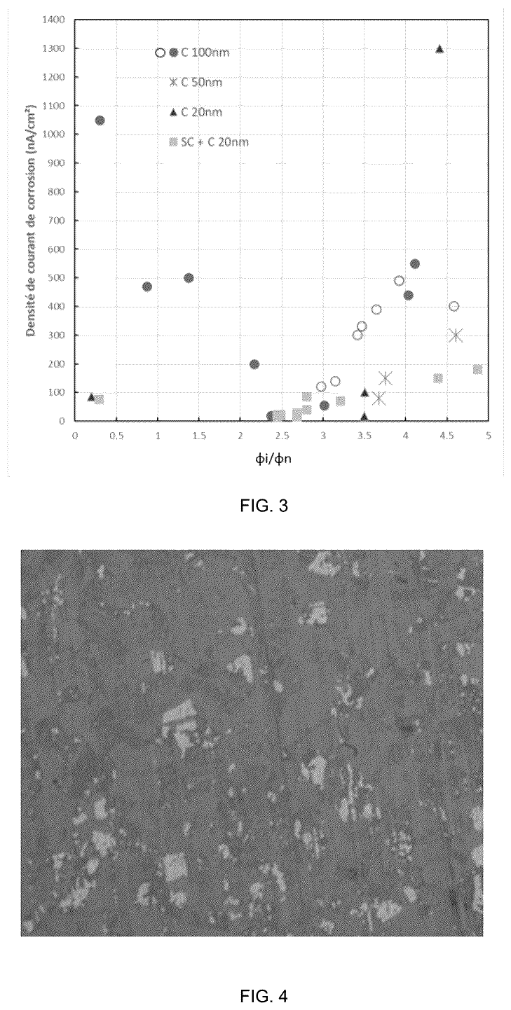

The performance is obtained by the validation of criteria of good resistance to corrosion, of good mechanical strength, of low ICR, and of low oxygen content, of the deposited layer, such as they are described in detail below in relation to FIGS. 3 to 10.

This table shows that the ratio between the flow of ions (φi) and the flow (φn) of neutral carbon atoms is an essential parameter. The power, linked to this ratio, must clearly not be zero. The presence of a metal sublayer, as well as the thickness of the deposited layer are parameters that are possible to adjust to optimise the mechanical and physical properties of said deposited layer.

In reference to FIG. 3, the Applicant has performed several series of deposition tests, by making the following parameters vary:
presence or not of a metal sublayer (SC) between the material (M) layer and the substrate (S);
thickness of the material (M) layer;
ratio between the flow of ions (φi) and the flow (φn) of neutral carbon atoms directed toward the substrate.

The corrosion current density is evaluated, in order to make a first selection from among the results obtained. It is reminded that the corrosion current density illustrates the resistance to the corrosion of the deposited layer: a low corrosion current indicates a good corrosion resistance in the test medium.

The corrosion current density is measured at the end of a 24-hour potentiostatic test at potential +0.8V/ref(Ag/AgCl).

The results of FIG. 3 show a dispersion of the points of each series, however the corrosion current density passes through a minimum to a flow ratio range (φi)/(φn) of between 2.2 and 3.1. There is therefore a preferable range of this flow ratio (φi)/(φn) to obtain a good corrosion resistance: a minimum bombardment is necessary to ensure a good corrosion resistance of the layer, but a bombardment which is too strong is also damaging, in that it causes a degradation of the layer and a high increase of corrosion. This is valid for the different deposited carbon layer thicknesses, that a metal sublayer (SC) is deposited beforehand or not.

In reference to FIG. 4, scanning electron microscopy observations are made on a substrate (S) having received a titanium sublayer then a deposited 20 nm thick carbon layer by being subjected to a bombardment of the ion assistance which is too strong (flow ratio (φi)/(φn) equal to 4.4). These observations show that after corrosion test at 0.8V, lacks of coating appear on the surface of the sample, where the carbon layer is no longer present and the titanium sublayer is stripped at the bright spots. Despite the presence of a titanium sublayer (SC), a 20 nm thick carbon-based material (M) layer is not sufficient, such that the coated substrate (S) has optimum properties: it is necessary that the carbon-based material (M) layer is deposited according to the criteria defined by the invention, namely that the flow ratio (φi)/(φn) is suitable.

Another means of evaluating the quality of the covering and of the protection provided by the deposition to the substrate is a corrosion test in a saline medium. The sample is immersed in a 35 g/L sodium chloride solution, similar to seawater, at ambient temperature for 3 hours. A potential is applied to the sample from the balance potential E0 up to +0.8V, then the potential decreases down to −0.4V before returning to E0 (versus reference Ag/AgCl) at a scanning speed of 1 mV/s. The current is measured during 2 cycles.

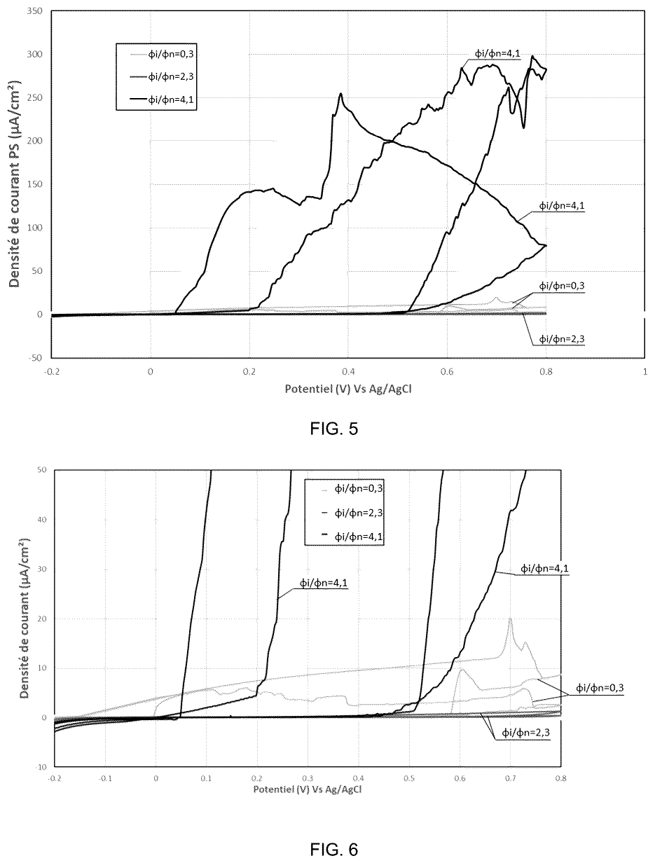

FIGS. 5 and 6 illustrate voltammetry graphs, relating to the corrosion current density measured in a saline medium. The sample is immersed in a 35 g/L NaCl solution (similar to seawater) at ambient temperature. Then the potential applied on the sample is cycled twice between −0.4V and 0.8V (versus a reference Ag/AgCl) and the current is measured.

The three tested samples are substrates (S) in 316L on which a carbon-based material (M) layer measuring 100 nm thick has been deposited:
the deposition of the first sample does not correspond to the invention, with a flow ratio (φi)/(φn) of 0.3;
the deposition of the second sample corresponds to the invention, with a flow ratio (φi)/(φn) of 2.3;
the deposition of the third sample does not correspond to the invention, with a flow ration (φi)/(φn) of 4.1.

In FIG. 5, it is seen that:
the first sample has a moderate corrosion current;
the second sample corresponding to the invention has a very low corrosion current;
the third sample has a sudden current increase when the potential exceeds 0.5V.

This corresponds to the corrosion by pitting of stainless steel in an NaCl medium, a well-known phenomenon. Coming from the test, the stainless steel foil is pierced in several points.

In FIG. 6, which is a detailed view of FIG. 5, it is observed that:
the first sample has a current increase, certainly limited, but which also corresponds to the pitting of the stainless steel;
the second sample corresponding to the invention has a very low current, since the anodic current is less than 1 μA/cm².

It can therefore be deduced that the carbon layers deposited with a flow ratio (φi)/(φn) which is too low or too high do not effectively protect the substrate (S) from corrosion, while the carbon layer deposited with a flow ratio (φi)/(φn) in the range corresponding to the invention protects the substrate (S) optimally.

In particular, these corrosion resistance tests show that a carbon-based material (M) layer which is too bombarded, does not effectively protect the substrate (S) or the sublayer (SC): local defects (lacks) in the layer appear in the corrosive medium. The subsequent stripping of the sublayer (SC) or of the substrate (S) in the corrosive medium causes their corrosion, and at least the entire salting-out in a metal cation solution that they release. In a cell, these are damaging to the durability of the membrane-electrode assembly, and therefore of the cell.

Complementarily to the corrosion resistance, it is relevant to be interested in the surface conductivity of the coated substrates (S). Indeed, a substrate (S) coated with a metal sublayer (SC) then a carbon layer can have a good corrosion resistance, which can be explained in certain cases by a passivation of the material of the sublayer (SC) in case of degradation of the carbon layer. However, this passivated material is not conductive enough on the surface, which means that a bipolar plate functionalised with such a deposition protects a fuel cell from an accidental degradation, however the performance of this fuel cell would be less (low yield due to significant ohm losses).

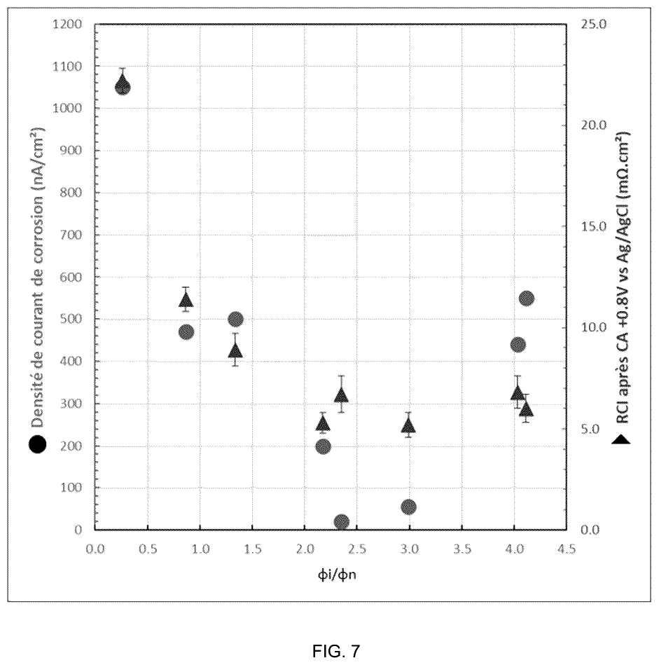

In reference to the graph of FIG. 7, the Applicant is focused on a series of 100 nm thick layer deposition tests. This graph summarises, according to the flow ratio (φi)/(φn):
the corrosion current densities, with the left scale,
the ICR obtained after the substrates (S) have been subjected to the corrosion test, which simulates an accelerated ageing of said substrates (S), with the right scale.

On this graph, it is observed that in the case of 100 nm carbon layer depositions without metal sublayer, and with a flow ratio range (φi)/(φn) of between 2.2 and 3.1, not only is a good resistance to corrosion obtained, but in addition, a good ICR is obtained, since the values are always less than 10 mΩ·cm². Measuring only the ICR does not make it possible to choose a particular flow ratio, but confirms that the flow ratio range (φi)/(φn) selected is relevant for the particular application of fuel cells, as the ICR is low.

Other more severe corrosion tests have been performed, always with the aim of improving the service life of the electrochemical systems integrating the functionalised substrates (S). In these tests, the duration is brought to 1 hour and the potential at 1.4V and 1.6V (versus ref(Ag/AgCl)). These severe tests have been performed on different substrates (S) having received carbon layers of different thicknesses and comprising a sublayer (SC) or not.

The carbon consumption under these corrosion conditions is progressive:
the 20 nm and 50 nm carbon layers are fully consumed, and the substrate (S) or the metal sublayer (SC) is stripped over almost the entire surface of the substrates (S);
the 100 nm, 160 nm, or 300 nm layers are not fully consumed: the tested surface keeps a black appearance: a certain carbon deposition thickness is always present on the surface, which makes it possible to preserve the good surface conduction properties of the coating with a low ICR.

It is therefore interesting to deposit a sufficient high carbon thickness to ensure a good resistance from the treatment to accidental overpotentials which could occur during the use of a cell, i.e. with dynamic operating conditions (with a cycling of the potential), or also a cycling for starting and stopping the cell (which lead to a greater cathode potential, or also the presence of air brought into contact with dihydrogen in the anodic medium upon start-up), etc.

Naturally, the maximum thickness of the carbon layer is limited by the cost of the treatment, linked to the necessary deposition duration.

The Applicant is then interested in the structure and in the chemical composition of compliant depositions.

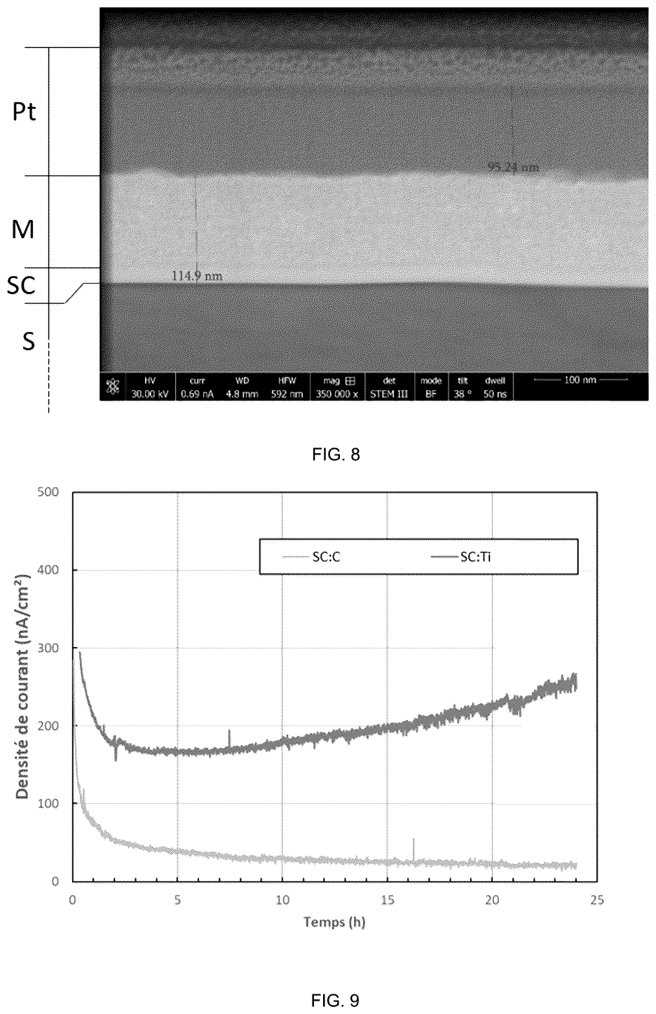

In reference to FIG. 8, a compliant deposition obtained according to the following parameters can be observed:
deposition on the substrate (S) of a carbon sublayer (SC), obtained by performing a low ion-assisted magnetron sputtering, i.e. that the flow ratio (φi)/(φn) is only 0.3;
deposition of a dense carbon layer (M), obtained by performing the ion-assisted magnetron sputtering according to the invention, i.e. that the flow ratio (φi)/(φn) is 2.5.

In order to be able to perform the cut by ion beam, a platinum layer (Pt) in different forms is deposited on the part to protect it during the cut, and can be seen in FIG. 8, but this layer does not return into the scope of the method.

On this sample:
the carbon sublayer (SC) in contact with the substrate (S) measures around 17 nm thick;
the dense carbon layer (M) deposited on the sublayer (SC) measures around 98 nm thick;
the total thickness of the deposition therefore measures around 115 nm thick.

In reference to FIG. 9, the Applicant has compared the evolution over 24 hours of the corrosion current density measured in potentiostatic test at 0.8V (versus reference Ag/AgCl) for two samples having received a 100 nm carbon layer deposited with a flow ratio of 2.3 corresponding to the invention. The first sample has received a carbon sublayer beforehand (deposited with a flow ratio of 0.3), and the second sample has received a titanium sublayer beforehand.

This test, the duration of which is extended, is an ageing test, similar to the test of FIG. 3, with the difference that in the present case, more specifically the evolution of the current density is represented over time.

It is observed that:
the first sample with carbon sublayer has a low corrosion current, and particularly that it decreases over time;
the second sample has a corrosion current which is a little greater, but particularly which tends to increase with time. This result suggests that the service life of the second sample will be lower than that of the first sample.

This test demonstrates that to obtain an even greater service life, a carbon sublayer is preferable to a metal sublayer.

However, a metal sublayer can have interests according to the type of substrate used:
if the substrate (S) is made of stainless steel, a metal sublayer made of titanium makes it possible, in case of degradation of the carbon-based material (M) layer, to create a passivation layer which guarantees that the stainless steel of the substrate (S) will not emit metal cations in the electrochemical system;
if the substrate (S) is made of titanium, a metal sublayer also made of titanium can make it possible to improve the adherence of the coatings then deposited.

A particular embodiment can therefore comprise:
the substrate (S);
a first metal sublayer (SC) deposited on the substrate (S);
a second carbon-based sublayer (SC) deposited on the first metal sublayer (SC);
a carbon-based material (M) layer deposited on the second carbon-based sublayer (SC).

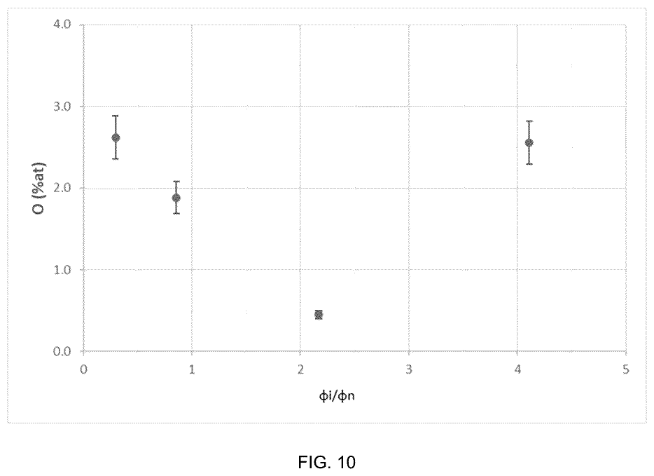

In reference to FIG. 10, chemical characterizations by nuclear reaction analysis (NRA) of material (M) layers deposited on substrates according to the flow ratio (φi)/(φn) have then been performed. The interest of these characterizations is to be able to find, from a functionalised plate by deposition, if the latter has been performed according to parameters according to the invention. There are techniques other than NRA for characterising the oxygen content of a deposition:
for example, X-ray photoelectron spectrometry (XPS). This technique is not accurate enough for dosing very low quantities of oxygen, and the results can be biased by ion abrasion;
or also secondary-ion mass spectrometry (SIMS), but this technique is not quantitative.

For these reasons, the Applicant has selected NRA as a reliable and quantitative technique for dosing oxygen in the carbon layer.

Expectedly, the carbon-based material (M) layer mainly comprises carbon, since the sputtered target is carbon-based. However, the residual oxygen rate varies according to the flow ratio (φi)/(φn):
if the ion-assisted bombardment is not sufficient (ratio less than 1.7), the oxygen is not expelled from the growth deposition layer. The residual oxygen content is therefore greater than or equal to around 1% at.
when the flow ratio (φi)/(φn) increases, the oxygen content decreases and seems to pass through a minimum within the flow ratio range corresponding to the invention.
then, when the ion-assisted bombardment is too high (flow ratio (φi)/(φn) greater than 3.5), it is observed that the oxygen content increases again. This can be explained by the appearance of local defects and carbon-oxygen bonds, and/or by the local stripping of the substrate (defect of the deposition, or greater constraint of the deposition which is too bombarded causing a tendency for the local delamination of the deposition of the substrate). In the latter case, the substrate is passivated, and oxygen is found in the passivation layer.

A functionalised plate according to the invention therefore comprises within the functional layer, an oxygen content less than 1% at, and preferably less than 0.7% at, calculated as the number of oxygen atoms with respect to the number of carbon atoms within said functional layer.

The functional layer can also comprise argon coming from ion assistance (or another noble gas, if a gas other than argon is used).

FIG. 11 illustrates a non-functionalised monopolar plate (60), on which the channels for conveying gases and for discharging water vapour can be distinguished, which have been shaped prior to the deposition of a functional layer.

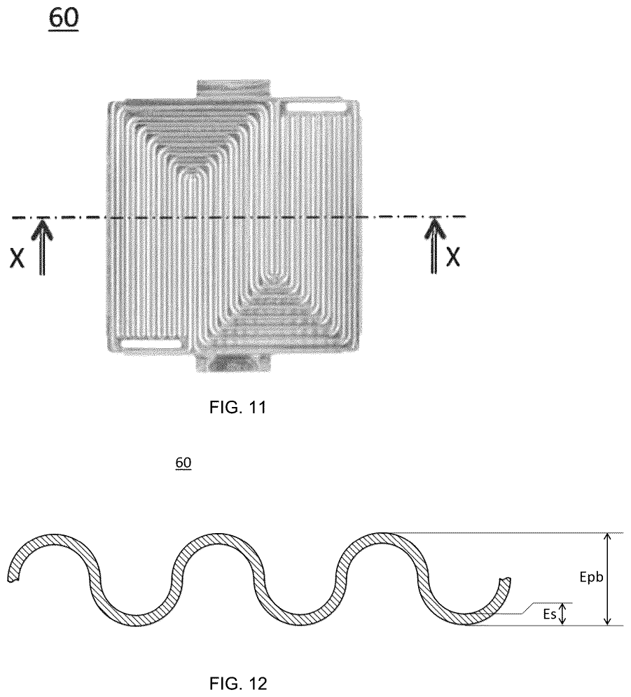

FIG. 12 is a diagram illustrating a partial view of a cut of such a bipolar plate (60). On this diagram, it is seen that the thickness of the substrate (Es) is less than the thickness (Epb) of the bipolar plate (60). Indeed, the thickness of the final plate (60) depends on the way in which this is shaped.

The method according to the invention actually makes it possible to functionalize the substrates (S):
by providing low ICR values, not only before but also after corrosion test;
by providing a good protection against corrosion, even over significant durations and high potentials;
the deposited layer having a good structural quality, since it does not have defects of the droplet type, for example;
the method not requiring a high temperature, which removes the potential risks for the adherence or the diffusion of the deposited material, as well as for the deformation of the plate;
the method being compatible with different types of parts, such as sheets, monopolar or bipolar plates (optionally already welded and assembled), and constituted of different stainless steel-, titanium-, alloy of the Inconel® type-based materials, i.e. a nickel, chromium and iron-based alloy.

In the case of using a complementary plasma source (40), it is possible to adjust the ion bombardment independently from the sputtering source and thus adapt the bombardment from one treatment to another, and optionally within a stack.

Moreover, the method can be performed differently from the examples given without moving away from the scope of the invention, which is defined by the claims.

In a variant not represented, the plasma (P) from the ion assistance is not generated by microwaves. Indeed, this is not the power consumed by the plasma source (40) which is significant, but the quantity of ions available at the substrates (S), hence the interpretation of the flow of ions ((φi) proposed by the Applicant. Other ion sources can therefore be used.

Closed-field unbalanced magnetron sputtering is also possible. These variants can require to correctly adjust the imbalance of the magnetrons and the looping of the field lines between cathodes to arrive at the desired flow ratio range.

Furthermore, the technical features of the different embodiments and variants mentioned above can be, totally or for some of them, combined with one another. It is, for example, possible to produce only one carbon-based sublayer (SC), only one metal sublayer (SC), or a carbon-based sublayer (SC) as well as a metal sublayer (SC). Thus, the method and the installation (1) can be adapted in terms of costs, functionalities and performance.

1. A method for depositing, with ion assistance, of an outer layer of a carbon-based material (M) from a target onto a metal substrate (S), by cathode sputtering, wherein the ratio between the flow of ions ((i) directed toward the substrate (S) and the flow ((φn) of neutral carbon atoms directed toward the substrate (S) is adjusted between 1.7 and 3.5, and a bias voltage of between −35V and −100V is applied to the substrate (S).

2. The method according to claim 1, wherein the ratio between the flow (φi) of gaseous ions and the flow ((φn) of neutral carbon atoms is between 2 and 3.1.

3. The method according to claim 1, wherein the material (M) deposited on the substrate (S) forms a layer called thin layer, having a thickness greater than or equal to 20 nm.

4. The method according to claim 1, wherein the substrate (S) comprises a stainless steel, titanium, a titanium alloy, or a nickel, chromium and iron-based alloy.

5. The method according to claim 1, wherein the flow of ions is generated by a magnetron cathode.

6. The method according to claim 5, wherein the flow of ions is generated by a system complementary to the magnetron cathode, preferably by microwave plasma.

7. The method according to claim 6, wherein the substrate (S) scrolls within an installation in front of a magnetron cathode sputtering station, then in front of a plasma (P) generation station, preferably cyclically.

8. The method according to claim 1, wherein the substrate (S) is a plate of thickness of between 10 μm and 1000 μm.

9. The method according to claim 1 comprising a prior step of depositing a carbon-based sublayer (SC) on the substrate (S) intended to be located between the substrate (S) and the outer layer of the carbon-based material (M), in contact with said carbon-based material (M), and that the ratio between the flow of ions (φi) directed toward the substrate (S) and the flow (φn) of neutral carbon atoms directed toward the substrate is adjusted to a value less than 1, the flow of ions being non-zero.

10. The method according to claim 9, wherein the thickness of the carbon-based sublayer (SC) is between 2 and 40 nm.

11. The method according to claim 1, comprising a prior step of depositing a metal sublayer (SC) on the substrate (S) intended to be located between the substrate (S) and the outer layer of the carbon-based material (M), in contact with said substrate (S), the material of the metal sublayer (SC) being chosen from among one or more of the following materials: chromium, titanium, zirconium, tantalum, or their alloys, as well as their nitrides and carbides.

12. The method according to claim 11, wherein the thickness of the metal sublayer (SC) is between 5 and 100 nm.

13. The method according to claim 1, wherein the bias voltage is between −50V and −75V.

14. A method for manufacturing a monopolar or bipolar plate comprising a metal substrate (S) covered with an outer layer comprising a carbon-based material (M), characterised in that it comprises a step of depositing said carbon-based material (M) from a target on said metal substrate (S), by magnetron cathode sputtering, by the implementation of a deposition method according to claim 1.

15. A part which can be obtained by a method for depositing an outer layer of a carbon-based material (M) from a target onto a metal substrate (S), by ion-assisted cathode sputtering of a target of carbon, according to claim 1, said part having an external surface comprising said metal substrate (S) coated with a carbon-based material (M) layer, and wherein the carbon-based material (M) layer comprises less than 1% at of oxygen, calculated as the number of oxygen atoms with respect to the number of carbon atoms within the carbon-based material (M) layer.

16. The method according to claim 2, wherein the material (M) deposited on the substrate (S) forms a layer called thin layer, having a thickness between 20 nm and 500 nm.

17. The method according to claim 1 comprising a prior step of depositing a carbon-based sublayer (SC) on the substrate (S) intended to be located between the substrate (S) and the outer layer of the carbon-based material (M), in contact with said carbon-based material (M), and that the ratio between the flow of ions (φi) directed toward the substrate (S) and the flow (φn) of neutral carbon atoms directed toward the substrate is adjusted to a value less than 0.5, the flow of ions being non-zero.

18. The method according to claim 9, wherein the thickness of the carbon-based sublayer (SC) is between 10 nm and 30 nm.

19. The method according to claim 11, wherein the thickness of the metal sublayer (SC) is between 20 nm and 40 nm.

20. The method according to claim 19, wherein the bias voltage is between −50V and −75V.
